(19) United States
(12) Patent Application Publication
(10) Pub. No.: US 2005/0184405 A1
(43) Pub. Date: Aug. 25, 2005

(54) Semiconductor package for lowering electromagnetic interference and method for fabricating the same

(76) Inventors: Jin-Chung Bai, Miaoli (TW); Chi-Pang Huang, Miaoli (TW)

Correspondence Address: EITAN, PEARL, LATZER & COHEN ZEDEK LLP, 10 ROCKEFELLER PLAZA, SUITE 1001, NEW YORK, NY, 10020, US

(21) Appl. No.: 10/913,386

(22) Filed: Aug. 9, 2004

(30) Foreign Application Priority Data
Feb. 24, 2004 (TW) 093104545

(51) Int. Cl. H01L 23/28

(52) U.S. Cl. 257/787

(57) ABSTRACT

A semiconductor package for lowering electromagnetic interference and a method for fabricating the same are proposed. The semiconductor package includes a chip carrier, at least one chip attached and electrically connected to the chip carrier, and an encapsulation body formed on the chip carrier for encapsulating the chip. The encapsulation body includes an electromagnetic absorbing layer made of an organic material filled with a plurality of porous metal particles. The electromagnetic absorbing layer absorbs electromagnetic waves generated by the chip and converts the electromagnetic waves to heat so as to improve the heat dissipation efficiency and reduce electromagnetic interference for the semiconductor package.

### PRIOR APPLICATION DATA

The present application claims benefit from prior Taiwan, R.O.C. application serial number 093104545 filed on Feb. 24, 2004.

### FIELD OF THE INVENTION

The present invention relates to semiconductor packages for lowering electromagnetic interference and methods for fabricating the same, and more specifically, to a semiconductor package in which electromagnetic waves are converted to heat and dissipated to lower the electromagnetic interference, and a fabrication method of the semiconductor package.

### BACKGROUND OF THE INVENTION

With the rapid development of electronic and digital industry, functional requirements of electronic products become more demanded. Therefore, researchers directed to semiconductor packages have focused on ways to improve the techniques of semiconductor fabrication and integrated circuit design to fabricate high-frequency chips with more functionality. For a semiconductor package using a high-frequency chip, conventionally a substrate or lead frame usually serves as a chip carrier. Referring to FIG. 7, a high-frequency semiconductor chip 61 is mounted on a chip carrier 60, and a plurality of bonding wires 64 electrically connect bond pads on the chip 61 to a corresponding area of the chip carrier 60. Then, an encapsulation body 66 is used to encapsulate the chip 61 and the bonding wires 64 to form a semiconductor package. The chip carrier 60 can be electrically connected to an external electronic device so as to transmit signals from the chip 61 to the external electronic device.

However, a severe problem of electromagnetic waves is usually caused during the operation of the foregoing semiconductor chip. The high-frequency chip 61 produces strong electromagnetic waves 75 during its operation such as performing calculation or transmission, making the electromagnetic waves 75 transmitted to the outside through the encapsulation body 66 and causing electromagnetic interference (EMI) to the surrounding electronic devices. This situation may further degrade the electrical performance and heat dissipation effect of the semiconductor package. Referring to FIG. 8A, a metal mask 70 is used to cover the encapsulation body 66, and provides grounding effect and electromagnetic shielding effect for preventing the electromagnetic waves 75 generated by the chip 61 from being emitted to the outside of the semiconductor package.

The above package design of FIG. 8A desirably lowers the EMI to the surrounding external devices but does not consider the EMI with the inside of the semiconductor package. Referring to FIG. 8B, although the metal mask 70 prevents outward emitting of the electromagnetic waves 75, it cannot absorb the electromagnetic waves 75 and thus leads to continuous reflection of the electromagnetic waves 75 in the encapsulation body 66. These electromagnetic waves 75 may not only influence the quality of electrical transmission between the chip 61 and the bonding wires 64 but also generate a large amount of heat in the encapsulation body 66 due to energy attenuation of the electromagnetic waves 75, thereby leading to a heavy burden on heat dissipation of the semiconductor package.

Additionally, the metal mask 70 usually has a relatively larger weight and higher material cost, and its mounting method cannot be performed through automatic mass production. Thus, the use of the metal mask 70 does not comply with the development trends such as light weight, low cost and high mass production of semiconductor packages, which is considered a trouble for packaging high-frequency chips.

Therefore, the problem to be solved here is to provide a semiconductor package and a method for fabricating the same, which can solve the EMI problem and achieve the benefits of high heat dissipation, low cost and profile miniaturization of the semiconductor package.

### SUMMARY OF THE INVENTION

A primary objective of the present invention is to provide a semiconductor package for lowering electromagnetic interference (EMI) and a method for fabricating the same, by which electromagnetic waves are converted to heat to reduce the EMI.

Another objective of the present invention is to provide a semiconductor package for lowering EMI and a method for fabricating the same, by which the semiconductor package has excellent heat dissipation effect.

Still another objective of the present invention is to provide a semiconductor package for lowering EMI and a method for fabricating the same, by which the semiconductor package is cost-effective and simple to be fabricated.

A further objective of the present invention is to provide a semiconductor package for lowering EMI and a method for fabricating the same, by which the semiconductor package has a reduced weight.

A further objective of the present invention is to provide a semiconductor package for lowering EMI and a method for fabricating the same, by which the semiconductor package has ideal electrical quality.

In accordance with the above and other objectives, the present invention proposes a semiconductor package for lowering EMI comprising: a chip carrier; at least one chip mounted on and electrically connected to the chip carrier; and an encapsulation body formed on the chip carrier for encapsulating the chip, the encapsulation body comprising an electromagnetic absorbing layer for absorbing electromagnetic waves generated by the chip and converting the electromagnetic waves to heat, wherein the electromagnetic absorbing layer is made of an organic material filled with a plurality of porous metal particles.

A method for fabricating the semiconductor package proposed in the present invention comprises the steps of: preparing a chip carrier; mounting at least one chip on the chip carrier and electrically connecting the chip to the chip carrier; forming an encapsulation body on the chip carrier for encapsulating the chip; and forming an electromagnetic absorbing layer on the encapsulation body for absorbing electromagnetic waves generated by the chip and converting the electromagnetic waves to heat, wherein the electromagnetic absorbing layer is made of an organic material filled with a plurality of porous metal particles.

A heat sink or another encapsulation body can further be formed on the electromagnetic absorbing layer. The electromagnetic absorbing layer may be fabricated by a screen-printing technique. The organic material of the electromagnetic absorbing layer is same as or different from a material for forming the encapsulation body. Moreover, the chip carrier can be a substrate or lead frame.

The semiconductor package for lowering electromagnetic interference and the method for fabricating the same proposed in the present invention employ an electromagnetic absorbing layer having a plurality of porous metal particles for absorbing electromagnetic waves from the chip and converting the absorbed electromagnetic waves into heat that can be dissipated. The present invention not only solves the problem of electromagnetic interference without having to use the conventional metal mask, but also significantly improves the electrical quality and heat dissipation efficiency of the semiconductor package as well as provides advantages such as reduction of the fabrication cost and the package weight, such that the prior-art drawbacks are eliminated.

### BRIEF DESCRIPTION OF THE DRAWINGS

The present invention can be more fully understood by reading the following detailed description of the preferred embodiments, with reference made to the accompanying drawings, wherein:

FIG. 1 is a cross-sectional view of a semiconductor package for lowering electromagnetic interference according to a first preferred embodiment of the present invention;

FIGS. 2A to 2D are cross-sectional views showing the procedural steps of a method for fabricating the semiconductor package according to the first preferred embodiment of the present invention;

FIG. 3 is a cross-sectional view of the semiconductor package according to a second preferred embodiment of the present invention;

FIG. 4 is a cross-sectional view of the semiconductor package according to a third preferred embodiment of the present invention;

FIG. 5 is a cross-sectional view of the semiconductor package according to a fourth preferred embodiment of the present invention;

FIG. 6 is a cross-sectional view of the semiconductor package according to a fifth preferred embodiment of the present invention;

FIG. 7 (PRIOR ART) is a cross-sectional view of a conventional semiconductor package;

FIG. 8A (PRIOR ART) is a cross-sectional view of a conventional semiconductor package provided with a metal mask; and

FIG. 8B (PRIOR ART) is a schematic diagram showing the reflection of electromagnetic waves in the conventional semiconductor package with the metal mask.

### DETAILED DESCRIPTION OF THE PREFERRED EMBODIMENTS

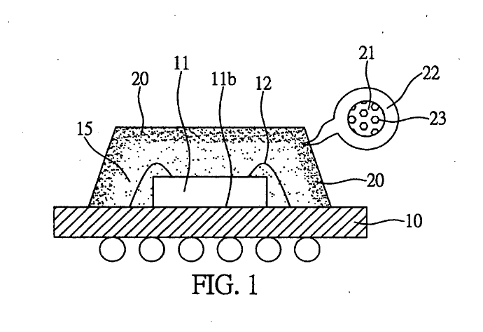

The preferred embodiments of a semiconductor package for lowering electromagnetic interference (EMI) and a method for fabricating the same proposed in the present invention are described in the following with reference to FIGS. 1 to 6.

The semiconductor packages according to a first preferred embodiment of the present invention is shown in FIG. 1, using a substrate 10 as a chip carrier. A high-frequency chip 11 is mounted with its inactive surface 11b on the substrate 10 and electrically connected to a conductive trace layer (not shown) of the substrate 10a via a plurality of bonding wires 12. An encapsulation body 15 made of a resin material such as an epoxy resin is formed on the substrate 10 to encapsulate the chip 11 and the bonding wires 12. The encapsulation body 15 comprises an electromagnetic absorbing layer 20 for absorbing electromagnetic waves generated by the chip 11 and converting the absorbed electromagnetic waves into heat. In this embodiment, the electromagnetic absorbing layer 20 is formed on the surface of the encapsulation body 15. It should be understood that the electromagnetic absorbing layer 20 can also be located within the encapsulation body 15.

The electromagnetic absorbing layer 20 is made of an organic material 22 filled with a plurality of porous metal particles 21. The organic material 22 can be the same resin material (such as epoxy resin) as or different from that for fabricating the encapsulation body 15. The porous metal particles 21 have a plurality of nano-scale pores 23 and are uniformly distributed in the organic material 22. When the chip 11 generates electromagnetic waves generated during operation, the electromagnetic waves are emitted to the electromagnetic absorbing layer 20 and absorbed by the porous metal particles 21, such that the electromagnetic waves are not reflected to the chip 11 or the substrate 10. The porous configuration of the metal particles 21 dramatically reduces the vibration amplitude of the absorbed electromagnetic waves in an excited state, thereby reducing the kinetic energy and resulting in energy attenuation of the electromagnetic waves. As a result, the electromagnetic waves cannot keep being reflected but are converted into heat with its energy level being reduced, and the heat can be dissipated out of the semiconductor package. This is a characteristic feature of the present invention, which not only solves the prior-art problems of electromagnetic interference and reflection of electromagnetic waves but also improves the heat dissipation efficiency of the semiconductor package through the energy conversion mechanism of the electromagnetic absorbing layer 20, thereby effectively reducing the fabrication cost and the overall weight of the semiconductor package.

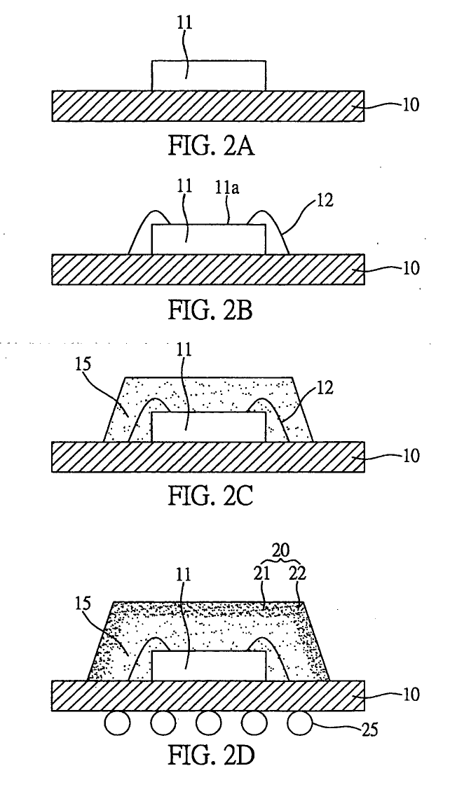

FIGS. 2A to 2D show the procedural steps of a method for fabricating the semiconductor package according to the above first embodiment. Referring to FIG. 2A, the first step is to prepare a substrate 10 and mount a chip 11 on an upper surface of the substrate 10. Then, referring to FIG. 2B, a plurality of bonding wires 12 are formed to electrically connect bond pads (not shown) on an active surface 11a of the chip 11 to a conductive trace layer (not shown) of the substrate 10 so as to provide transmission of electrical signals. Referring to FIG. 2C, a conventional molding process is performed to form an encapsulation body 15 on the upper surface of the substrate 10 to encapsulate the chip 11 and the plurality of bonding wires 12. Lastly, referring to FIG. 2D, an electromagnetic absorbing layer 20 is formed on the surface of the encapsulation body 15 by a screen-printing technique, wherein the electromagnetic absorbing layer 20 is made of an organic material 22 filled with a plurality of porous metal particles 21. It should be understood that besides screen-printing, the electromagnetic absorbing layer 20 can also be fabricated by other methods. Moreover, a plurality of solder balls 25 are implanted on a lower surface of the substrate 10 to transmit the electrical signal from the chip 11 to the outside.

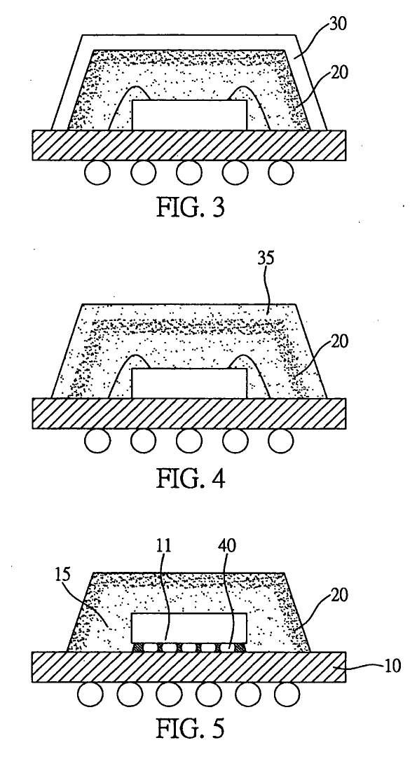

Besides the above first embodiment, the semiconductor package proposed in the present invention may also be structured according to a second preferred embodiment shown in FIG. 3. The second embodiment differs from the first embodiment in that there is a heat sink 30 attached to the electromagnetic absorbing layer 20, such that the heat caused from conversion of the electromagnetic waves in the electromagnetic absorbing layer 20 can be rapidly dissipated outside through the heat sink 30 that is in contact with the electromagnetic absorbing layer 20, thereby improving the overall heat dissipation efficiency of the semiconductor package. Alternatively, according to a third preferred embodiment shown in FIG. 4, another encapsulation body 35 can be formed on the electromagnetic absorbing layer 20 to reinforce the structural strength of the semiconductor package and achieve the intended improvements. The encapsulation body 35 can be made of a resin material same as or different from that of the above encapsulation body 15 for encapsulating the chip 11.

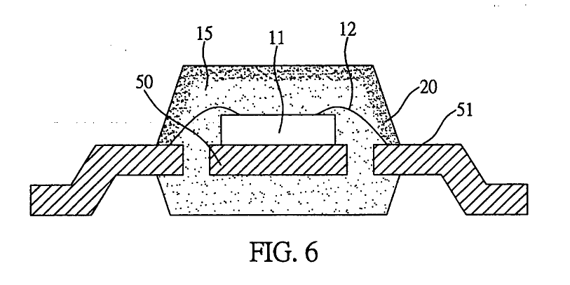

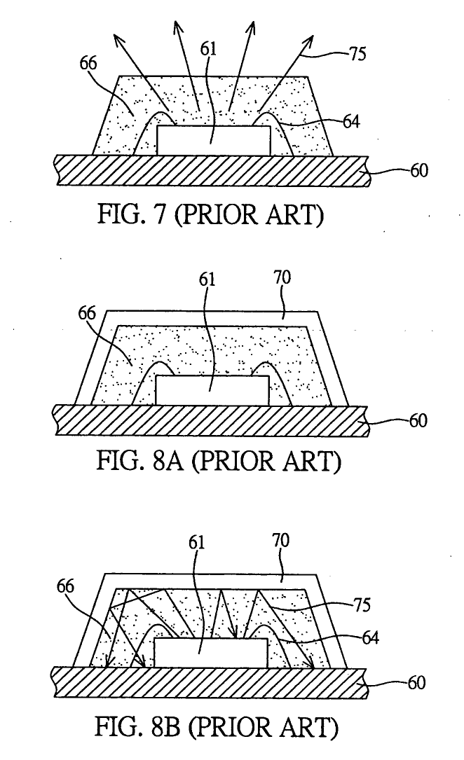

Furthermore, besides the bonding wires 12 described in the foregoing embodiments, referring to a fourth preferred embodiment shown in FIG. 5, the chip 11 can also be mounted on the substrate 10 in a flip-chip manner and electrically connected to the substrate 10 via a plurality of conductive bumps 40. Then, after the encapsulation body 15 for encapsulating the chip 11 is fabricated, the electromagnetic absorbing layer 20 is formed on the encapsulation body 15 to achieve the above improvements such as reduction of electromagnetic interference, increase in heat dissipation efficiency, and decrease in weight. In addition, the chip carrier in the present invention is not limited to the substrate 10 described in the foregoing embodiments. According to a fifth preferred embodiment shown in FIG. 6, the chip 11 is mounted on a lead frame 50 and electrically connected to a plurality of leads 51 of the lead frame 50 via the bonding wires 12. Similarly, the electromagnetic absorbing layer 20 can be formed on the encapsulation body 15 as previously described to achieve the effects such as reduction of electromagnetic interference, improvement in heat dissipation efficiency, and decrease in weight.

Therefore, the semiconductor package for lowering electromagnetic interference and the method for fabricating the same proposed in the present invention employ an electromagnetic absorbing layer having a plurality of porous metal particles for absorbing electromagnetic waves from the chip and converting the absorbed electromagnetic waves into heat that can be dissipated. The present invention not only solves the problem of electromagnetic interference without having to use the conventional metal mask, but also significantly improves the electrical quality and heat dissipation efficiency of the semiconductor package as well as provides advantages such as reduction of the fabrication cost and the package weight.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

1. A semiconductor package for lowering electromagnetic interference, comprising:
a chip carrier;
at least one chip mounted on and electrically connected to the chip carrier; and
an encapsulation body formed on the chip carrier for encapsulating the chip, wherein the encapsulation body comprises an electromagnetic absorbing layer for absorbing electromagnetic waves generated by the chip, and the electromagnetic absorbing layer is made of an organic material filled with a plurality of porous metal particles.

2. The semiconductor package of claim 1, wherein the electromagnetic absorbing layer converts the absorbed electromagnetic waves to heat.

3. The semiconductor package of claim 1, wherein the electromagnetic absorbing layer is formed on the encapsulation body.

4. The semiconductor package of claim 1, wherein the electromagnetic absorbing layer is formed within the encapsulation body.

5. The semiconductor package of claim 1, wherein the porous metal particles of the electromagnetic absorbing layer absorb the electromagnetic waves and reduce energy of the absorbed electromagnetic waves.

6. The semiconductor package of claim 1, wherein the organic material of the electromagnetic absorbing layer is same as a material for forming the encapsulation body.

7. The semiconductor package of claim 1, wherein the organic material of the electromagnetic absorbing layer is different from a material for forming the encapsulation body.

8. The semiconductor package of claim 1, further comprising a heat sink attached to the encapsulation body.

9. The semiconductor package of claim 1, wherein the chip is electrically connected to the chip carrier via a plurality of bonding wires or a plurality of flip-chip conductive bumps.

10. The semiconductor package of claim 1, wherein the chip carrier is a substrate or lead frame.

11. A method for fabricating a semiconductor package for lowering electromagnetic interference, the method comprising the steps of:
preparing a chip carrier;
mounting at least one chip on the chip carrier and electrically connecting the chip to the chip carrier;
forming an encapsulation body on the chip carrier for encapsulating the chip; and
forming an electromagnetic absorbing layer on the encapsulation body for absorbing electromagnetic waves generated by the chip, wherein the electromagnetic absorbing layer is made of an organic material filled with a plurality of porous metal particles.

12. The method of claim 11, wherein the electromagnetic absorbing layer converts the absorbed electromagnetic waves to heat.

13. The method of claim 11, further comprising attaching a heat sink to the electromagnetic absorbing layer.

14. The method of claim 11, further comprising forming another encapsulation body on the electromagnetic absorbing layer.

15. The method of claim 11, wherein the electromagnetic absorbing layer is formed by a screen-printing technique.

16. The method of claim 11, wherein the porous metal particles of the electromagnetic absorbing layer absorb the electromagnetic waves and reduce energy of the absorbed electromagnetic waves.

17. The method of claim 11, wherein the organic material of the electromagnetic absorbing layer is same as a material for forming the encapsulation body.

18. The method of claim 11, wherein the organic material of the electromagnetic absorbing layer is different from a material for forming the encapsulation body.

19. The method of claim 11, wherein the chip is electrically connected to the chip carrier by a wire-bonding technique or a flip-chip technique.

20. The method of claim 11, wherein the chip carrier is a substrate or lead frame.
